(19) United States
(12) Patent Application Publication
(10) Pub. No.: US 2026/0052930 A1
(43) Pub. Date: Feb. 19, 2026

(54) METHOD FOR CLEANING SILICON WAFER, METHOD FOR PRODUCING SILICON WAFER, AND SILICON WAFER

(71) Applicant: SUMCO Corporation, Tokyo (JP)

(72) Inventors: Kazuya FUKUSHIMA, Tokyo (JP); Ryoichi YANAI, Tokyo (JP); Ryosuke TAKAHASHI, Tokyo (JP)

(73) Assignee: SUMCO Corporation, Tokyo (JP)

(21) Appl. No.: 19/124,937

(22) PCT Filed: Aug. 8, 2023
(86) PCT No.: PCT/JP2023/028976

§ 371 Date: Apr. 28, 2025

(30) Foreign Application Priority Data
Nov. 15, 2022 (JP) 2022-182395

(51) Int. Cl. H01L 21/67; H01L 21/02; H01L 21/311

(52) U.S. Cl. CPC H01L 21/67051; H01L 21/02052; H01L 21/31111; H01L 21/67253

(57) ABSTRACT

In the method for cleaning a silicon wafer of this disclosure, an oxidizing agent is supplied in the surface layer modification process from a position shifted from the center of the silicon wafer in the radial direction. The method for producing a silicon wafer of this disclosure includes performing the above-mentioned method for cleaning a silicon wafer. When the silicon wafer of this disclosure is subjected to a given measurement, difference between maximum and minimum values of the thickness of the natural oxide film in the radial direction of the silicon wafer, when a thickness of the natural oxide film is normalized to a maximum value, is 0.1 or less.

### TECHNICAL FIELD

This disclosure relates to a method for cleaning a silicon wafer, a method for producing a silicon wafer, and a silicon wafer.

### BACKGROUND

On the surface of a silicon wafer, there is an oxide film that is formed in air at room temperature and an oxide film that is formed by chemical cleaning. These are referred to as a natural oxide film or a chemical oxide film (hereafter, referred to as a natural oxide film). The thickness of the natural oxide film is about a few tenths of a nanometer (around 0.2 nm) to 2 nm or less. The thickness of the natural oxide film formed in the cleaning process of a typical silicon wafer is around 5 Å (angstroms). In contrast, the oxide film formed by heat treatment is called thermal oxide film, and its thickness is 3 nm or more.

With the recent trend toward higher precision, more multi-layered and thinner semiconductor devices, there is a demand for thinner films of various types used in semiconductor devices. For example, as a method for improving the gate characteristics of MOS transistors, a method has been disclosed in which the silicon surface is cleaned immediately before the formation of a gate oxide film, the silicon surface is hydrogen-terminated, and then a gate insulating film is formed (see, for example, Patent Document 1). In order to improve the yield of the latest semiconductor devices, it is necessary to form an ultra-thin silicon oxide film such as a natural oxide film uniformly and reproducibly in a plane (for example, see Patent Document 2).

### CITATION LIST

### Patent Literature

PTL 1: JP 2000-216156 A1
PTL 2: JP 6791454 B1

### SUMMARY

### Technical Problem

An object of the present disclosure is to provide a method for cleaning a silicon wafer, a method for producing a silicon wafer, and a silicon wafer that are capable of improving uniformity of the thickness of the natural oxide film on a silicon wafer.

### Solution to Problem

The gist of the present disclosure is as follows.

(1) A method for cleaning a silicon wafer using a single wafer processing, comprising
a surface layer modification process in which a surface layer of the silicon wafer is modified using an oxidizing agent;
an etching process in which the surface layer of the silicon wafer after the surface layer modification process is etched using an etching solution; and
a rinsing process in which a surface of the silicon wafer is rinsed using an rinse solution, wherein
in the surface layer modification process, the oxidizing agent is supplied from a position shifted from a center of the silicon wafer in a radial direction.

Here, “the oxidizing agent is supplied from a position shifted from a center of the silicon wafer in a radial direction” means that the intersection of: the extension line of the extending direction of the supply tube that supplies the oxidizing agent; and the surface of the silicon wafer; is offset from the center of the silicon wafer in the radial direction, and that the oxidizing agent is supplied from a supply tube at such a position.

(2) The method for cleaning a silicon wafer using a single wafer processing as described in the (1) above, wherein the oxidizing agent is ozonated water.

(3) The method for cleaning a silicon wafer using a single wafer processing as described in the (1) or (2) above, wherein the etching solution is an aqueous solution of hydrogen fluoride.

(4) The method for cleaning a silicon wafer using a single wafer processing as described in the (1) or (2) above, wherein the rinse solution is pure water.

(5) The method for cleaning a silicon wafer using a single wafer processing as described in the (1) or (2) above, wherein the position at which the oxidizing agent is supplied is shifted by 5 mm or more and 75 mm or less from the center of the silicon wafer in the radial direction.

(6) The method for cleaning a silicon wafer using a single wafer processing as described in the (5) above, wherein the position at which the oxidizing agent is supplied is shifted by 15 mm or more and 20 mm or less from the center of the silicon wafer in the radial direction.

(7) The method for cleaning a silicon wafer using a single wafer processing as described in any one of the (1) to (6) above, wherein the oxidizing agent is ozonated water, the etching solution is an aqueous solution of hydrogen fluoride, a concentration of the ozonated water is within a range of 20 to 30 ppm, and a concentration of the aqueous solution of hydrogen fluoride is within a range of 0.5 to 3.0 mass %.

(8) The method for cleaning a silicon wafer using a single wafer processing as described in any one of the (1) to (7) above, wherein rotational speed of the silicon wafer in the surface layer modification process, the etching process, and the rinsing process is within a range of 100 to 500 rpm.

(9) The method for cleaning a silicon wafer using a single wafer processing as described in any one of the (1) to (8) above, including measuring a thickness of a natural oxide film at intervals of 29.4 mm from the center of the silicon wafer with a diameter of 300 mm using a spectroscopic ellipsometer, and adjusting at least one of: the position at which the oxidizing agent is supplied; a concentration of the oxidizing agent; a concentration of the etching solution; flow rate of the oxidizing agent; flow rate of the etching solution; rotational speed of the silicon wafer so that difference between maximum and minimum values of the thickness of the natural oxide film in the radial direction of the silicon wafer, when a thickness of the natural oxide film is normalized to a maximum value, is 0.1 or less.

(10) A method for producing a silicon wafer, including the method for cleaning a silicon wafer as described in any one of the (1) to (9).

(11) A silicon wafer with a natural oxide film with a thickness of 2 nm or less, wherein when a thickness of the natural oxide film is measured at intervals of 29.4 mm from a center of the silicon wafer with a diameter of 300 mm to a position of 147 mm using a spectroscopic ellipsometer, difference between maximum and minimum values of the thickness of the natural oxide film in the radial direction of the silicon wafer, when a thickness of the natural oxide film is normalized to a maximum value, is 0.1 or less.

### Advantageous Effect

According to the present disclosure, it is possible to provide a method for cleaning a silicon wafer, a method for producing a silicon wafer, and a silicon wafer that are capable of improving uniformity of the thickness of the natural oxide film on a silicon wafer.

### BRIEF DESCRIPTION OF THE DRAWINGS

In the accompanying drawings:

FIG. 1 is a flowchart of a method for cleaning a silicon wafer in accordance with one embodiment of the present disclosure;

FIG. 2 schematically illustrates the relative positions of a silicon wafer, and supply tubes of an oxidizing agent and an etching solution;

FIG. 3 illustrates measurement points for the thickness of a natural oxide film on a wafer in Example;

FIG. 4 provides the measurement results of the thickness of a natural oxide film that has been formed;

FIG. 5 provides the results of normalizing the thickness of the natural oxide film in FIG. 4 by its maximum value;

FIG. 6 provides the results of a comparison of the uniformity of the thickness of the natural oxide film by types of chemical solution;

FIG. 7 provides the thickness distribution of the natural oxide film when the rotational speed of the silicon wafer is changed during the final treatment with ozonated water; and

FIG. 8 provides the results of normalizing the thickness of the natural oxide film in FIG. 7 by its maximum value.

### DETAILED DESCRIPTION

Hereinafter, an embodiment of the present disclosure will be described in detail with reference to the drawings.

### <Method for Cleaning Silicon Wafer>

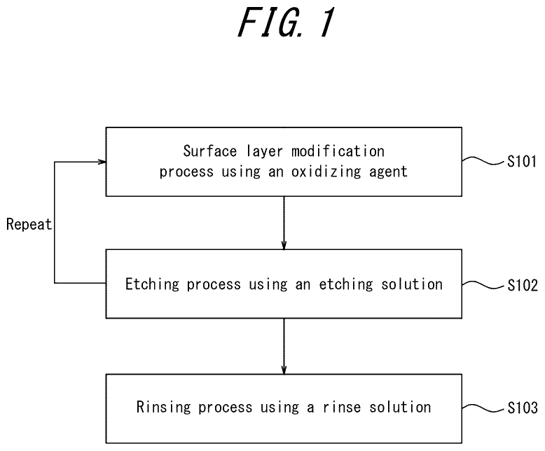

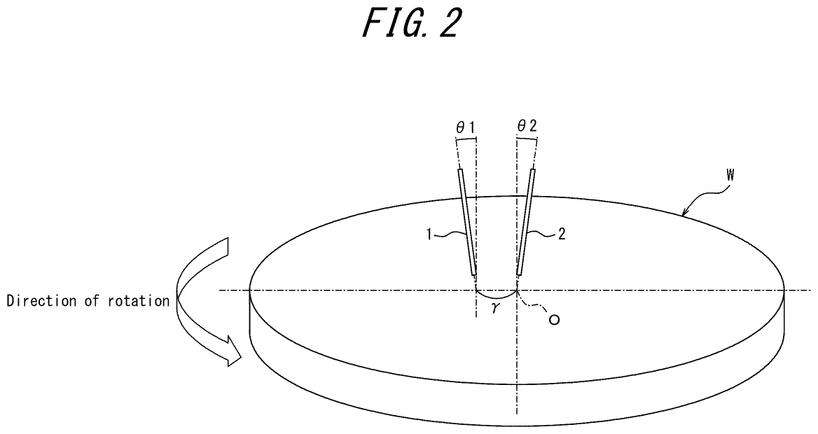

FIG. 1 is a flowchart of a method for cleaning a silicon wafer in accordance with one embodiment of the present disclosure. FIG. 2 schematically illustrates the relative positions of a silicon wafer, and supply tubes of an oxidizing agent and an etching solution.

The method for cleaning a silicon wafer of this embodiment is a method for cleaning a wafer using a single wafer processing which uses a single-wafer spin cleaning machine. The method for cleaning a silicon wafer using a single wafer processing herein refers to a method of cleaning a wafer surface by supplying desired chemical solution from a chemical solution supply nozzle towards the wafer surface while the wafer is rotated horizontally with its center as the central axis. As illustrated in FIG. 1, in the method of this embodiment, first, a surface layer of the silicon wafer W is modified using an oxidizing agent (Surface layer modification process: step S101). In this process, as illustrated in FIG. 2, while rotating the silicon wafer W, an oxidizing agent (in this case, ozonated water) is supplied to the surface of the silicon wafer W via a supply tube 1, so that it comes into contact with the surface of the silicon wafer W to form a natural oxide film on the surface of the silicon wafer W. Prior to step S101, it is also possible to perform SC-1 (Standard Clean 1) cleaning or SC-2 (Standard Clean 2) cleaning as appropriate.

The oxidizing agent is preferably ozonated water. The concentration of the ozonated water is preferably within a range of 20 to 30 ppm. By setting the concentration of the ozonated water to 20 ppm or more, it is possible to form a natural oxide film of sufficient thickness, while, in light of the limit of ozone solubility in water, the upper limit of the concentration is around 30 ppm. The ppm here refers to the weight ratio. The flow rate of the ozonated water is preferably 0.5 to 1.5 L/min. The processing time using the ozonated water is preferably between 15 and 60 seconds.

Here, as illustrated in FIG. 2, in this embodiment, the oxidizing agent (in this example, ozonated water) is supplied from a position shifted from a center O of the silicon wafer W in the radial direction (towards the edge of the wafer W). More specifically, the position at which the oxidizing agent is supplied is preferably a position that is shifted by 5 mm or more and 75 mm or less from the center O of the silicon wafer W in the radial direction, and is more preferably a position that is shifted by 15 mm or more and 20 mm or less from the center O of the silicon wafer W in the radial direction.

Next, the surface layer of the silicon wafer W is etched using an etching solution (Etching process: step S102). In this process, as illustrated in FIG. 2, while rotating the silicon wafer W, etching solution (in this case, an aqueous solution of hydrogen fluoride) is supplied to the surface of the silicon wafer W via a supply tube 2, so that it comes into contact with the surface of the silicon wafer W. This causes the natural oxide film formed in the surface layer modification process (step S101) to be etched. It will be noted that, in this process (at least in the final etching process if step S102 is carried out multiple times), the amount of etching should be such that a natural oxide film remains.

The etching solution is preferably an aqueous solution of hydrogen fluoride. The concentration of the aqueous solution of hydrogen fluoride is preferably within the range of 0.5 to 3.0 mass %. This is because a concentration of 0.5% or more of the aqueous solution of hydrogen fluoride provides sufficient etching effect, while a concentration of 3.0% or less of the aqueous solution of hydrogen fluoride prevents excessive etching. The flow rate of the aqueous solution of hydrogen fluoride is preferably 0.5 to 1.5 L/min. The processing time with the aqueous solution of hydrogen fluoride is preferably 1 to 10 seconds.

As illustrated in FIG. 2, in this embodiment, the etching solution (in this case, the aqueous solution of hydrogen fluoride) is supplied from the center O of the silicon wafer W (without being shifted in the radial direction). However, the etching solution may be supplied from a position shifted from the center O of the silicon wafer W in the radial direction.

In this embodiment, as illustrated in FIG. 1, after repeating the surface layer modification process (step S101) and the etching process (step S102) a predetermined number of times (e.g., 2 to 4 times), the process proceeds to a rinsing process (step S103) described below. It will be noted that the surface layer modification process (step S101) and the etching process (step S102) do not necessarily have to be repeated. In addition, including the rinsing process (step S103), the surface layer modification process (step S101), the etching process (step S102), and the rinsing process (step S103) can be repeated (for example, 2 to 4 times).

Next, the rinsing process (step S103) using a rinse solution is performed. In this process, while rotating the silicon wafer W, rinse solution (in this case, pure water) is supplied to the surface of the silicon wafer W via a separate supply tube (not illustrated in the drawings) from the supply tubes 1 and 2, so that to wash away foreign matter on the surface of the silicon wafer W.

The rinse solution is preferably pure water, and more preferably DIW (deIonized water). The flow rate of pure water is preferably 0.5 to 1.5 L/min. The processing time with pure water is preferably 1 to 30 seconds. In this embodiment, the pure water is supplied from the center O of the silicon wafer W (without being shifted in the radial direction). However, the pure water may be supplied from a position shifted from the center O of the silicon wafer W in the radial direction.

In steps S101 to S103, the rotational speed of the silicon wafer W during cleaning is preferably within the range of 100 to 500 rpm.

The following explains the effects of the method for cleaning a silicon wafer in this embodiment.

The present inventors have conducted extensive research into the cause of the non-uniformity in the thickness of the natural oxide film on a silicon wafer, and have found that in the conventional method in which the oxidizing agent (ozonated water) is supplied from the center O of the silicon wafer W, while the silicon wafer is subjected to centrifugal force in the radial direction (from the center to the edge) due to the rotation of the silicon wafer, the supplied oxidizing agent (ozonated water) flows from the center O in the radial direction, waving concentrically, forming a peak in the supply amount near the point R/2 when the diameter is R, for example, or on the outer circumference, and this is the cause of the non-uniformity in the thickness of the natural oxide film in the plane.

Therefore, in this embodiment, in a single-wafer cleaning process that uses an oxidizing agent, an etching solution, and a rinsing solution, the oxidizing agent (ozonated water) is supplied from a position that is offset from the center O of the silicon wafer W in the radial direction in the surface layer modification process (step S101) that uses the oxidizing agent. This avoids the supplied oxidizing agent (ozonated water) flowing from the center O in the radial direction, waving concentrically, thus the above-mentioned peak in the supply amount of the oxidizing agent can be reduced.

Therefore, according to the method of cleaning a silicon wafer of the present disclosure, it is possible to improve the uniformity of the thickness of the natural oxide film on the silicon wafer W. It is assumed that the oxide film with uniform thickness formed by the cleaning process will maintain its uniformity even after the subsequent thermal oxidation process, and it is expected to lead to improved yields in the production of semiconductor devices.

Here, as mentioned above, it is preferable that the position at which the oxidizing agent (ozonated water) is supplied is shifted by 5 mm or more and 75 mm or less from the center of the silicon wafer W in the radial direction. By shifting it from the center of the silicon wafer W by 5 mm or more in the radial direction, the above effect can be obtained more reliably, while by shifting it from the center of the silicon wafer W by 75 mm or less in the radial direction, the amount of oxidizing agent (ozonated water) supplied to the center O of the silicon wafer W can be kept from being too small, and by these means, the uniformity of the thickness of the natural oxide film on the silicon wafer W can be improved more reliably. For the same reason, it is more preferable that the position at which the oxidizing agent (ozonated water) is supplied is shifted by 15 mm or more and 20 mm or less from the center O of the silicon wafer W in the radial direction.

Here, at least one of the following parameters can be used to fine-tune the uniformity of the thickness of the natural oxide film: the position at which the oxidizing agent (ozonated water) is supplied, the concentration of the oxidizing agent (ozonated water), the concentration of the etching solution (aqueous solution of hydrogen fluoride), the flow rate of the oxidizing agent (ozonated water), the flow rate of the etching solution (aqueous solution of hydrogen fluoride), and the rotational speed of the silicon wafer W.

In other words, for example, as an indicator of the uniformity of the natural oxide film, the thickness of the natural oxide film is measured at intervals of 29.4 mm from the center of the silicon wafer W with a diameter of 300 mm using a spectroscopic ellipsometer, the difference between maximum and minimum thickness of the natural oxide film in the radial direction of the silicon wafer W when the thickness of the natural oxide film is normalized to a maximum value is used as the target value, with the target value set to be 0.1 or less.

Then, in advance, data is obtained on the relationship between at least one of: the position at which the oxidizing agent is supplied; the concentration of the oxidizing agent; the concentration of the etching solution; the flow rate of the oxidizing agent; the flow rate of the etching solution; the rotational speed of the silicon wafer, and the uniformity of the thickness of the natural oxide film (e.g., the profile of in-plane thickness variation).

Based on the current cleaning conditions listed above and the in-plane profile of the thickness of the natural oxide film, the target value for the amount of thickness variation (amount of increase or decrease) in a specified area (position) within the silicon wafer plane is determined in order to achieve the above-mentioned target value.

Based on the data on the relationship, the correction values for each of the cleaning conditions that are suitable for achieving the target value for the amount of thickness variation in the specified area within the silicon wafer plane are obtained.

By adjusting at least one of the above cleaning conditions by the amount of the correction value obtained, and then performing the cleaning from the next time onwards, it is possible to further improve the uniformity of the natural oxide film on the silicon wafer.

As an example of a variation on the above fine-tuning, the above fine-tuning can also be performed using a method that uses artificial intelligence. In other words, an artificial intelligence model is created (with sufficient training data prepared in advance for machine learning) in which the amount of the thickness variation of the natural oxide film in a specified area (position) within the plane is used as the explanatory variable (input), and the correction value for at least one of the above cleaning conditions is used as the objective variable (output). Then, when the amount of the thickness variation of the natural oxide film in a specified area (position) within the plane (corresponding to the target value, for example, in which the difference between the maximum and minimum thicknesses of the natural oxide film in the radial direction of the silicon wafer W is 0.1 or less) is input into the artificial intelligence model created, the correction value for at least one of the above cleaning conditions is output by the machine learning section. Using the output as the corrected value, at least one of the above cleaning conditions is adjusted by the amount of the correction value obtained, and then the cleaning from the next time onwards is performed. It will be noted that any known machine learning algorithm, such as a neural network, can be used.

In the example illustrated in FIG. 2, when the direction perpendicular to the main surface of the silicon wafer is defined as the vertical direction, the supply tubes 1 and 2 are inclined from the edge to the center of the silicon wafer in the radial direction as they go from the top to the bottom (towards the side closer to the silicon wafer). The inclination angle θ1 of the supply tube 1 with respect to the vertical direction is not particularly limited, but may be 1 to 5°. The inclination angle θ2 of the supply tube 2 with respect to the vertical direction is not particularly limited, but may be 1 to 5°. These supply tubes 1 and 2 do not necessarily have to be inclined, and they may be extended in a vertical direction (without being inclined). In addition, even when inclined with respect to the vertical direction, the supply tubes 1 and 2 may be inclined from the inside to the outside of the silicon wafer as they go from the top to the bottom (towards the side closer to the silicon wafer).

### <Method for Producing Silicon Wafer>

The method for producing a silicon wafer according to one embodiment of the present disclosure includes performing the method for cleaning a silicon wafer according to the above embodiment. Other processes can include, as is known, the ingot pulling process, the slicing process, the polishing process, and others. According to the method for producing a silicon wafer of this embodiment, the uniformity of the thickness of the natural oxide film on the silicon wafer W can be improved.

### <Silicon Wafer>

The silicon wafer in accordance with one embodiment of the present disclosure is the silicon wafer after the method for cleaning a silicon wafer described above has been performed, and when the thickness of the natural oxide film is measured at intervals of 29.4 mm from a center of the silicon wafer with a diameter of 300 mm to a position of 147 mm using a spectroscopic ellipsometer, difference between the maximum and minimum values of the thickness of the natural oxide film in the radial direction of the silicon wafer, when a thickness of the natural oxide film is normalized to the maximum value, is 0.1 or less. As will be provided in the Example below, the method of this embodiment makes it possible to obtain a silicon wafer with a more uniform thickness of natural oxide film.

### Examples

The following describes examples of the present disclosure, however, the present disclosure is not limited to the following examples.

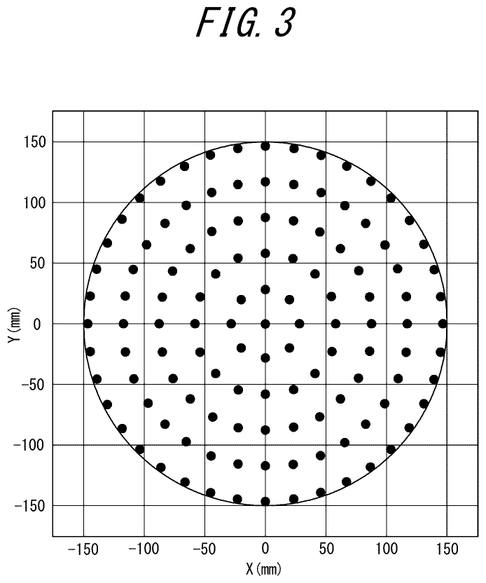

In this example, a p-type epitaxial silicon wafer with a diameter of 300 mm (hereafter, simply referred to as a silicon wafer) was used as a sample. First, a cleaning process was carried out for 15 seconds using ozonated water with an ozone concentration of 20 ppm and a wafer rotational speed of 300 rpm. Next, a cleaning process was carried out for 4 seconds with the aim of etching the oxide film, using a 1% aqueous solution of hydrogen fluoride and a silicon wafer rotational speed of 300 rpm. The etching process using a solution of hydrogen fluoride in this case was carried out under conditions where the oxide film was not completely removed. Next, a cleaning process was carried out for 30 seconds with the aim of forming an oxide film, using ozonated water with an ozone concentration of 20 ppm and a silicon wafer rotational speed of 300 rpm. In this way, the process of cleaning with the ozonated water and then with the aqueous solution of hydrogen fluoride was repeated three times. After that, a cleaning with DIW (deionized water) was carried out for 30 seconds. In all cleaning processes, the flow rate of the chemical solution was set at 1.0 L/min. The supply tube is inclined with respect to the epitaxial silicon wafer from the edge to the center of the silicon wafer in the radial direction as they go from the top to the bottom (towards the side closer to the silicon wafer), with an inclination angle of 4° with respect to the vertical direction. The position of the supply tube during the process with ozonated water was tested under three conditions: when it was centered on the wafer, and when it was shifted by 15 mm and 20 mm in the radial direction respectively from the center of the wafer. The thickness of the natural oxide film on the wafer was measured using a spectroscopic ellipsometer at intervals of 29.4 mm from the center of the wafer which has been subjected by the single-wafer cleaning, for a total of 121 measurement points. The measurement points are indicated by dots in FIG. 3.

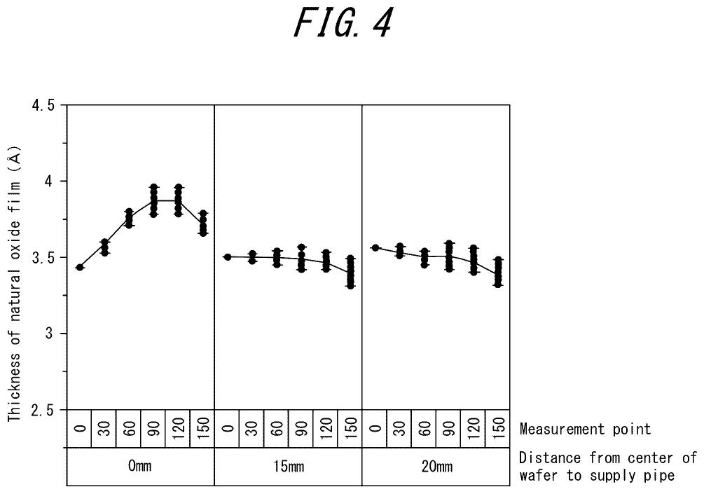

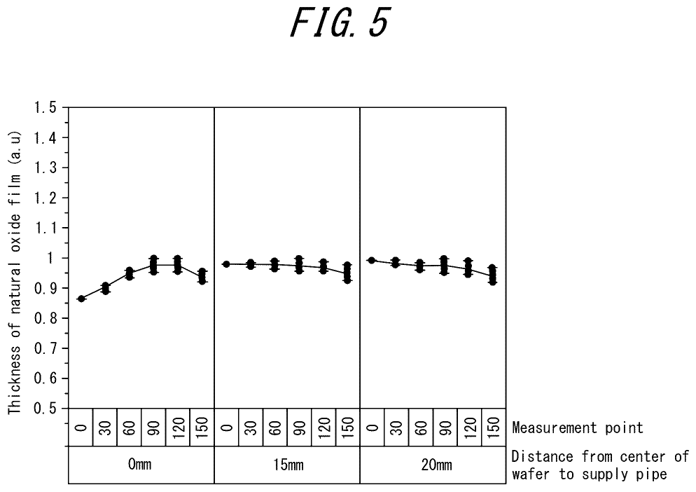

FIG. 4 provides the results of measuring the thickness of the natural oxide film that has been formed. As provided in FIG. 4, an oxide film of about 3 to 4 Å was formed on the wafers. FIG. 5 provides the results of normalizing the thickness of the natural oxide film in FIG. 4 by the maximum value. The horizontal axes in FIGS. 4 and 5 represent the measurement points (mm), which are expressed as the radial distance from the center of the wafer, and the radial distance (mm) from the center of the wafer to the supply tube. The vertical axis in FIG. 5 represents the thickness of the natural oxide film normalized to its maximum value. The lower the standard deviation of the in-plane distribution of the thickness of the natural oxide film, the more uniform the in-plane distribution. From this, we can see that the uniformity of the thickness of the natural oxide film within the plane of the silicon wafer is higher when the position of the ozonated water supply tube is shifted from the center of the wafer in the radial direction of the wafer than when the position of the ozonated water supply tube is at the center of the wafer.

With regard to FIG. 5, the relationship between the standard deviation of the thickness of the oxide film in the radial direction of the wafer and the difference between the maximum and minimum values is provided in Table 1 below. From Table 1, we can see that by shifting the position of the ozonated water supply tube from the center of the wafer in the radial direction of the wafer, the standard deviation and the difference between the maximum and minimum values decrease, i.e. the uniformity of the thickness of the oxide film within the plane of the silicon wafer increases. Also, when the distance from the center is 15 mm in the circumferential direction of the wafer, it is about the same as when the distance from the center is 20 mm in the circumferential direction of the wafer.

TABLE 1

| Distance from center of wafer | Standard | |
|---|---|---|
| to supply pipe (mm) | deviation | Max − Min |
| 0 | 0.03 | 0.13 |
| 15 | 0.02 | 0.07 |
| 20 | 0.02 | 0.08 |

As mentioned in the description of the embodiment, the cleaning conditions for a silicon wafer can also be adjusted by using the difference between the maximum and minimum values of the thickness of the natural oxide film within the wafer plane as an indicator. For example, if the difference between the maximum and minimum values of the thickness of the natural oxide film on a silicon wafer which has been cleaned under a certain cleaning condition is 0.1 or more, the in-plane distribution of the natural oxide film should be checked. If the thickness of the natural oxide film is thick around R/2 (where R is the diameter) or on the outer circumference, it is thought that the thickness of the natural oxide film can be improved by reducing the rotational speed of the silicon wafer during the final ozonated water processing, for example, as a cleaning condition to be adjusted.

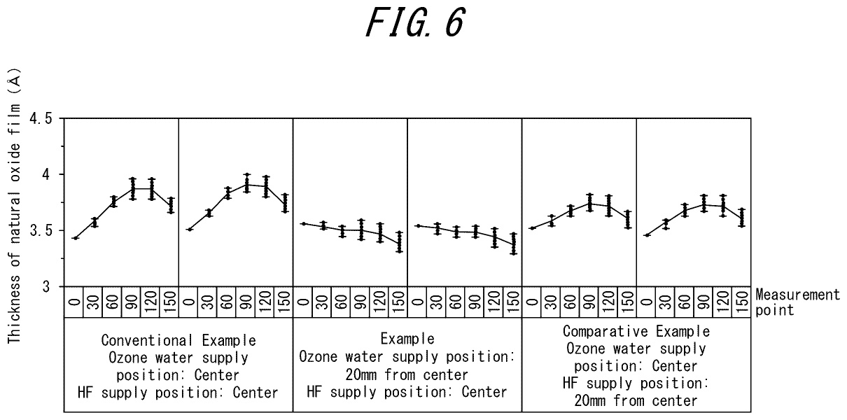

Next, the difference in the effect by shifting the supply position from the center of the wafer, depending on the chemical solutions to be supplied, was verified. FIG. 6 provides the results of a comparison of the uniformity of the thickness of the natural oxide film by type of chemical solution. Conventional Example provides a result when ozonated water, an aqueous solution of hydrogen fluoride, and pure water are all supplied from the center of the wafer. Example provides a result when the position of the ozonated water supply is shifted by 20 mm from the center of the wafer in the radial direction, and the aqueous solution of hydrogen fluoride and pure water is supplied from the center of the wafer. Comparative Example provides a result when the position of the aqueous solution of hydrogen fluoride supply is shifted 20 mm from the center of the wafer, and the ozonated water and the pure water are supplied from the center of the wafer. By comparing these, it can be seen that the uniformity of the thickness of the natural oxide film in Example was better than in Conventional Example and Comparative Example. In other words, good results were obtained when the position of the ozonated water supply was shifted from the center of the silicon wafer in the radial direction. Although the detailed mechanism is unknown, the inventors believe that the change in liquid film caused by the splash of liquid when a chemical solution such as ozonated water is discharged affects the variation in the reaction speed of the chemical solution in the radial direction of the wafer. In addition, the inventors believe that the removal and formation of the natural oxide film is not carried out uniformly by the treatment with ozonated water and a solution of hydrogen fluoride, but that the uniformity of the oxide film is ensured by the balance of the two chemical solutions.

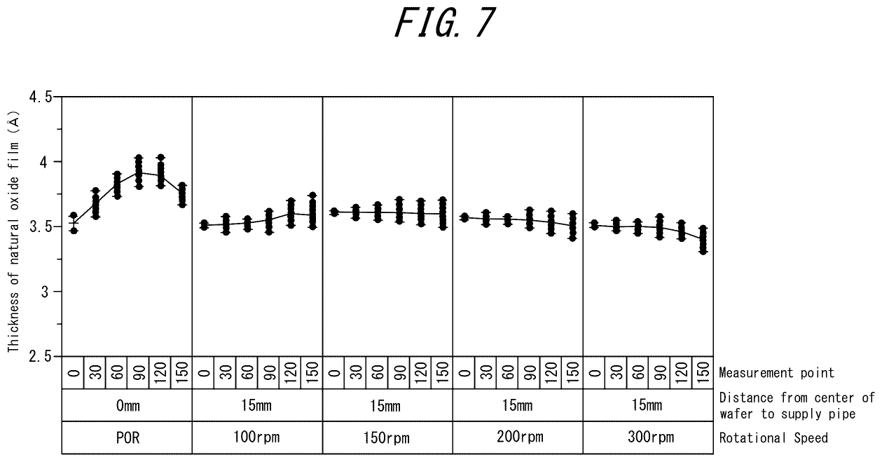

Next, verification was also carried out by changing the rotational speed of the silicon wafer during the final ozonated water supply when the position of the ozonated water supply was fixed at 15 mm from the center of the wafer. The rotational speeds were set at 100 rpm, 150 rpm, 200 rpm, and 300 rpm. FIG. 7 provides the thickness distribution of the natural oxide film when the rotational speed of the silicon wafer is changed during the final treatment with ozonated water. It can be seen that by reducing the rotational speed during the final supply of ozone water, it is possible to obtain an even better in-plane distribution of the thickness of the natural oxide film.

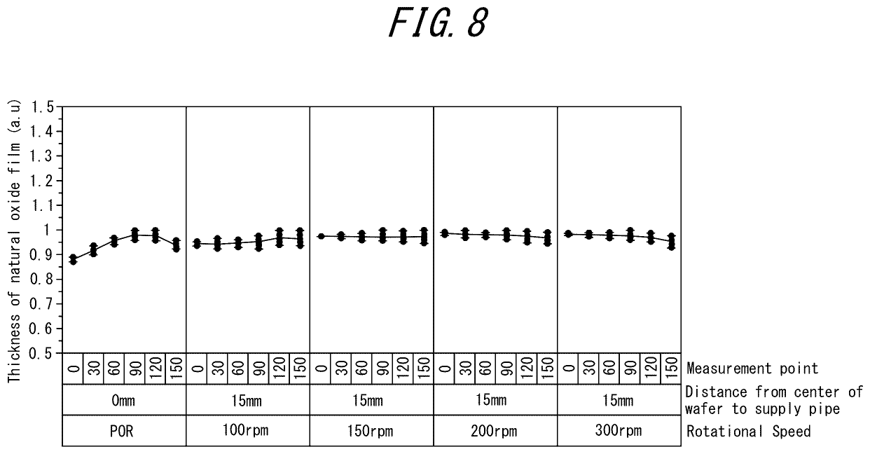

FIG. 8 provides the results of normalizing the thickness of the natural oxide film in FIG. 7 to its maximum value. In addition, the relationship between the standard deviation of the thickness of the natural oxide film in the radial direction of the wafer and the difference between the maximum and minimum values is provided in Table 2 below. From Table 2, it can be seen that by lowering the rotational speed of the silicon wafer during the final ozone water supply from the standard value (POR: Point of Reference), the standard deviation and the difference between the maximum and minimum values are even smaller than in the previous Example, therefore, it can be said that the uniformity of the thickness of the natural oxide film within the plane of the silicon wafer is extremely high. This is thought to be because the centrifugal force is reduced by lowering the rotational speed of the silicon wafer in the final ozone water treatment, which increases the oxidation reaction around the periphery, and the uniformity within the plane is further improved by the periphery being lifted.

TABLE 2

| Rotational | Standard | |
|---|---|---|
| speed | deviation | Max − Min |
| POR | 0.02 | 0.13 |
| 100 rpm | 0.02 | 0.07 |
| 150 rpm | 0.01 | 0.05 |
| 200 rpm | 0.01 | 0.06 |

### REFERENCE SIGNS LIST

1 Supply tube
2 Supply tube

1. A method for cleaning a silicon wafer using a single wafer processing, comprising
a surface layer modification process in which a surface layer of the silicon wafer is modified using an oxidizing agent;
an etching process in which the surface layer of the silicon wafer after the surface layer modification process is etched using an etching solution; and
a rinsing process in which a surface of the silicon wafer is rinsed using an rinse solution, wherein
in the surface layer modification process, the oxidizing agent is supplied from a position shifted from a center of the silicon wafer in a radial direction.

2. The method for cleaning a silicon wafer using a single wafer processing as described in claim 1, wherein the oxidizing agent is ozonated water.

3. The method for cleaning a silicon wafer using a single wafer processing as described in claim 1, wherein the etching solution is an aqueous solution of hydrogen fluoride.

4. The method for cleaning a silicon wafer using a single wafer processing as described in claim 1, wherein the rinse solution is pure water.

5. The method for cleaning a silicon wafer using a single wafer processing as described in claim 1, wherein the position at which the oxidizing agent is supplied is shifted by 5 mm or more and 75 mm or less from the center of the silicon wafer in the radial direction.

6. The method for cleaning a silicon wafer using a single wafer processing as described in claim 5, wherein the position at which the oxidizing agent is supplied is shifted by 15 mm or more and 20 mm or less from the center of the silicon wafer in the radial direction.

7. The method for cleaning a silicon wafer using a single wafer processing as described in claim 1, wherein
the oxidizing agent is ozonated water,
the etching solution is an aqueous solution of hydrogen fluoride,
a concentration of the ozonated water is within a range of 20 to 30 ppm, and a concentration of the aqueous solution of hydrogen fluoride is within a range of 0.5 to 3.0 mass %.

8. The method for cleaning a silicon wafer using a single wafer processing as described in claim 7, wherein rotational speed of the silicon wafer in the surface layer modification process, the etching process, and the rinsing process is within a range of 100 to 500 rpm.

9. The method for cleaning a silicon wafer using a single wafer processing as described in claim 1, including measuring a thickness of a natural oxide film at intervals of 29.4 mm from the center of the silicon wafer with a diameter of 300 mm using a spectroscopic ellipsometer, and adjusting at least one of: the position at which the oxidizing agent is supplied; a concentration of the oxidizing agent; a concentration of the etching solution; flow rate of the oxidizing agent; flow rate of the etching solution; rotational speed of the silicon wafer so that difference between maximum and minimum values of the thickness of the natural oxide film in the radial direction of the silicon wafer, when a thickness of the natural oxide film is normalized to a maximum value, is 0.1 or less.

10. A method for producing a silicon wafer, including the method for cleaning a silicon wafer as described in claim 1.

11. A silicon wafer with a natural oxide film with a thickness of 2 nm or less, wherein when a thickness of the natural oxide film is measured at intervals of 29.4 mm from a center of the silicon wafer with a diameter of 300 mm to a position of 147 mm using a spectroscopic ellipsometer, difference between maximum and minimum values of the thickness of the natural oxide film in the radial direction of the silicon wafer, when a thickness of the natural oxide film is normalized to a maximum value, is 0.1 or less.
